(19) United States
(12) Patent Application Publication
(10) Pub. No.: US 2022/0029135 A1
(43) Pub. Date: Jan. 27, 2022

(54) SPATIAL OPTICAL DIFFERENTIATORS AND LAYER ARCHITECTURES FOR OLED DISPLAY PIXELS

(71) Applicant: Applied Materials, Inc., Santa Clara, CA (US)

(72) Inventors: Chung-Chia CHEN, New Taipei City (TW); Byung-Sung KWAK, Mountain View, CA (US); Robert Jan VISSER, Menlo Park, CA (US); Chung-Chih WU, Taipei City (TW); Wei-Kai LEE, Taipei City (TW); Po-Hsiang LIAO, Taichung City (TW); Chang-Cheng LEE, Taichung City (TW)

(21) Appl. No.: 17/371,305

(22) Filed: Jul. 9, 2021

Related U.S. Application Data
(60) Provisional application No. 63/054,649, filed on Jul. 21, 2020.

(30) Foreign Application Priority Data
Jul. 2, 2021 (US) PCT/US2021/040321

(51) Int. Cl. H01L 51/52; H01L 51/56; H01L 27/32

(52) U.S. Cl. CPC H01L 51/5265; H01L 51/5253; H01L 2227/323; H01L 27/3262; H01L 51/56

(57) ABSTRACT

Embodiments described herein relate to spatial optical differentiators and layer architecture of adjacent functional layers disposed above or below organic light-emitting diode (OLED) display pixels. A functional unit for an electroluminescent (EL) device pixel includes a spatial optical differentiator disposed adjacent the EL device pixel. The spatial optical differentiator is configured to selectively reflect and transmit light based on an incident angle of light upon the functional unit. For top-emitting OLED, the functional unit includes a thin film encapsulation (TFE) stack disposed over the spatial optical differentiator. For bottom-emitting OLED, the functional unit includes the spatial optical differentiator disposed above at least one of a planar layer or an isolation layer. Also described herein are methods for fabricating the functional unit.

### CROSS-REFERENCE TO RELATED APPLICATIONS

This application claims the benefit of U.S. Provisional Patent Application Ser. No. 63/054,649, filed on Jul. 21, 2020 and PCT/US2021/040321 filed on Jul. 2, 2021, the entirety of which is herein incorporated by reference.

### BACKGROUND

### Field

Embodiments of the present disclosure generally relate to electroluminescent (EL) devices with improved outcoupling efficiency. More specifically, embodiments described herein relate to spatial optical differentiators and layer architecture of functional layers disposed adjacent to organic light-emitting diode (OLED) display pixels.

### Description of the Related Art

Organic light-emitting diode (OLED) technologies have become an important next-generation display technology offering many advantages (e.g., high efficiency, wide viewing angles, fast response, and potentially low cost). In addition, as a result of improved efficiency, OLEDs are also becoming practical for some lighting applications. Even so, typical OLEDs still exhibit significant efficiency loss between internal quantum efficiency (IQE) and external quantum efficiency (EQE).

Through certain combinations of electrode materials, carrier-transport layers, e.g., hole-transport layers (HTLs) and electron-transport layers (ETLs), emission layers (EMLs), and layer stacking, IQE levels can reach nearly 100%. However, EQE levels of typical OLED structures remain limited by optical outcoupling inefficiencies. Outcoupling efficiencies can suffer from optical energy loss due to significant emitting light being trapped by total internal reflection (TIR) inside the OLED display pixels.

Typical top-emitting OLED structures include a substrate, a reflective electrode over the substrate, organic layer(s) over the reflective electrode, and a transparent or semi-transparent top electrode over the organic layer(s). Due to higher refractive indices of the organic layer(s) (typically n>=1.7) and top electrode (typically n>=1.8) relative to air (n=1), significant emitting light is confined by TIR at the device-air interface preventing outcoupling to air.

Also in typical bottom-emitting OLED structures, in addition to the waveguided mode trapped within the OLED device, a significant portion of waveguided light is trapped in the substrate (e.g., n-value of about 1.5).

In addition to the above-referenced causes of reduced outcoupling, one or more layers of an adjacent functional unit built on top or bottom of the pixel architecture can independently reduce outcoupling. In top-emitting OLED, the adjacent functional unit may include thin film encapsulation (TFE) layers, color filters, optically clear adhesives (OCA), other similar structures, or combinations thereof. In bottom-emitting OLED, the adjacent functional unit may include one or more layers formed on a substrate, e.g., planar layers or isolation layers used in thin-film transistor (TFT) fabrication, other similar structures, or combinations thereof.

Accordingly, what is needed in the art are improved functional layer structures for OLED display pixels.

### SUMMARY

In one or more embodiments, a functional unit for an electroluminescent (EL) device pixel is provided. The functional unit includes a spatial optical differentiator disposed adjacent the EL device pixel. The spatial optical differentiator is configured to selectively reflect and transmit light based on an incident angle of light upon the functional unit.

In one or more embodiments, a method for fabricating a functional unit for an EL device pixel is provided. The method includes forming a first layer of a spatial optical differentiator adjacent the EL device pixel, the first layer having a first refractive index. The method includes forming a second layer of the spatial optical differentiator over the first layer, the second layer having a second refractive index. A difference between the first and second refractive indices is about 0.2 or greater. The method includes forming a third layer of the spatial optical differentiator over the second layer, the third layer having the first refractive index. The method includes forming a fourth layer of the spatial optical differentiator over the third layer, the fourth layer having the second refractive index. The spatial optical differentiator is configured to selectively reflect and transmit light based on an incident angle of light upon the functional unit.

In some embodiments, a display structure is provided. The display structure includes an array of electroluminescent (EL) device pixels. The display structure includes a functional unit disposed adjacent the array of EL device pixels. The functional unit comprises a spatial optical differentiator disposed adjacent the EL device pixel. The spatial optical differentiator is configured to selectively reflect and transmit light based on an incident angle of light upon the functional unit. The display structure includes a plurality of thin-film transistors forming a driving circuit array configured to drive and control the array of EL device pixels. The display structure includes a plurality of interconnection layers, each interconnection layer in electrical contact between an EL pixel and a respective thin-film transistor of the plurality of thin-film transistors.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic, top view of an array of electroluminescent (EL) devices, according to one or more embodiments.

FIG. 1B is a schematic, side view of the array of EL devices of FIG. 1A, according to one or more embodiments.

FIG. 1C-1H are schematic, side sectional views of various different EL devices taken along section line 1-1 of FIG. 1A, according to some embodiments.

FIG. 2A is a schematic diagram of an emission region of a top-emitting EL device, according to one or more embodiments.

FIG. 2B is a schematic diagram of an emission region of a bottom-emitting EL device, according to one or more embodiments.

FIG. 3A is a schematic, side sectional view of a functional unit according to one or more embodiments.

FIG. 3B is a schematic, side sectional view of another functional unit, according to one or more embodiments.

FIG. 3C is a schematic, side sectional view of yet another functional unit, according to one or more embodiments.

FIGS. 3D-3F are schematic, side sectional views of various different spatial optical differentiators, according to some embodiments.

FIG. 4 is a diagram illustrating a method for fabricating a functional unit for an EL device, according to one or more embodiments.

FIG. 5 is a diagram illustrating another method for fabricating a functional unit for an EL device, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein relate to spatial optical differentiators and layer architecture of adjacent functional layers disposed above or below organic light-emitting diode (OLED) display pixels. A functional unit for an electroluminescent (EL) device pixel includes a spatial optical differentiator disposed adjacent the EL device pixel. The spatial optical differentiator (also referred to as an “angularly selective optical film”) is configured to selectively reflect and transmit light based on an incident angle of light upon the functional unit. For top-emitting OLED, the functional unit includes a thin film encapsulation (TFE) stack disposed over the spatial optical differentiator. For bottom-emitting OLED, the functional unit includes the spatial optical differentiator disposed above at least one of a planar layer or an isolation layer. Also described herein are methods for fabricating the functional unit.

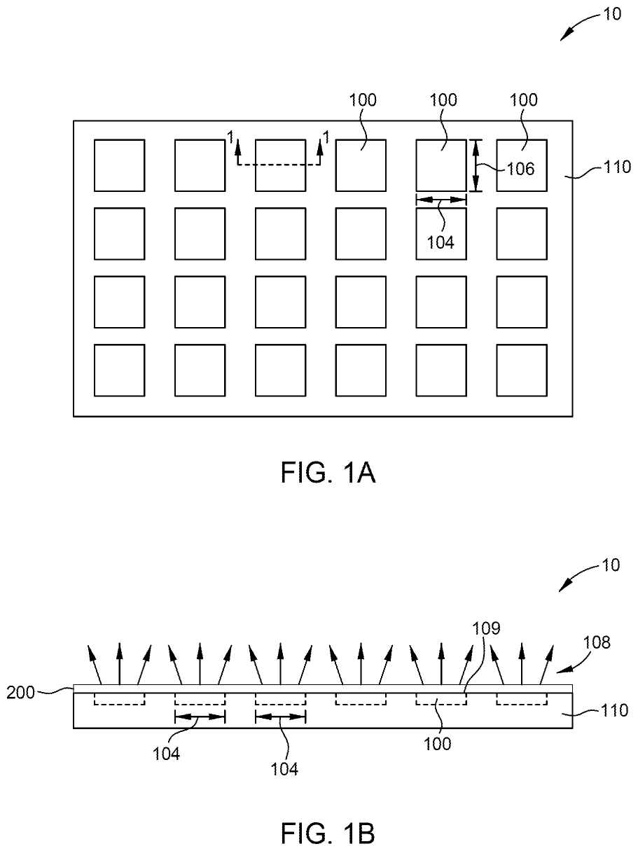

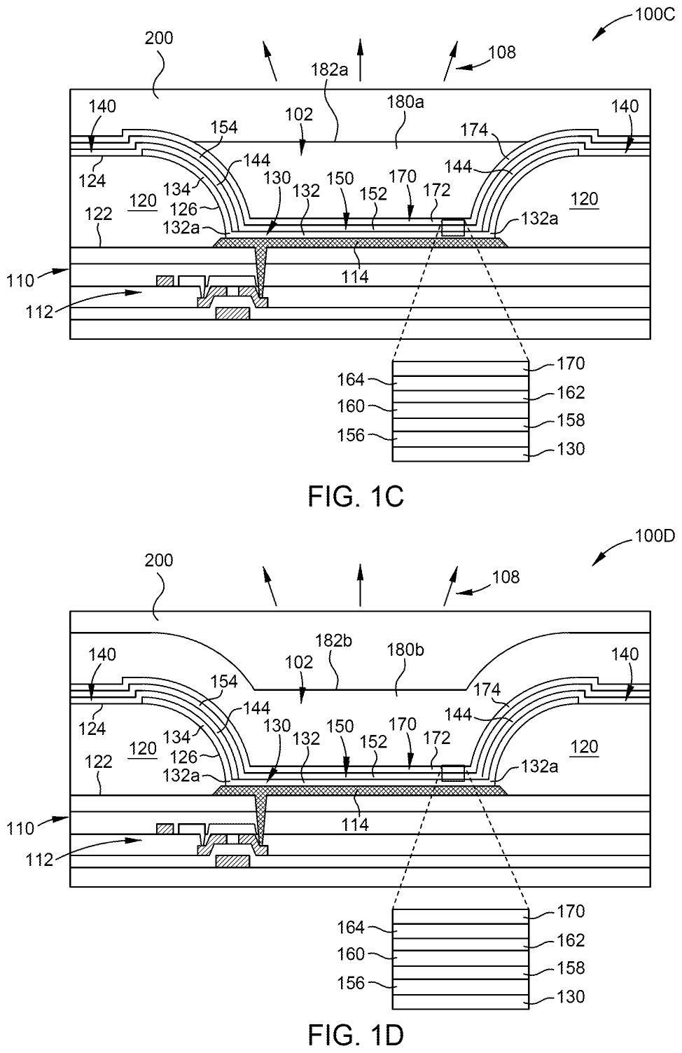

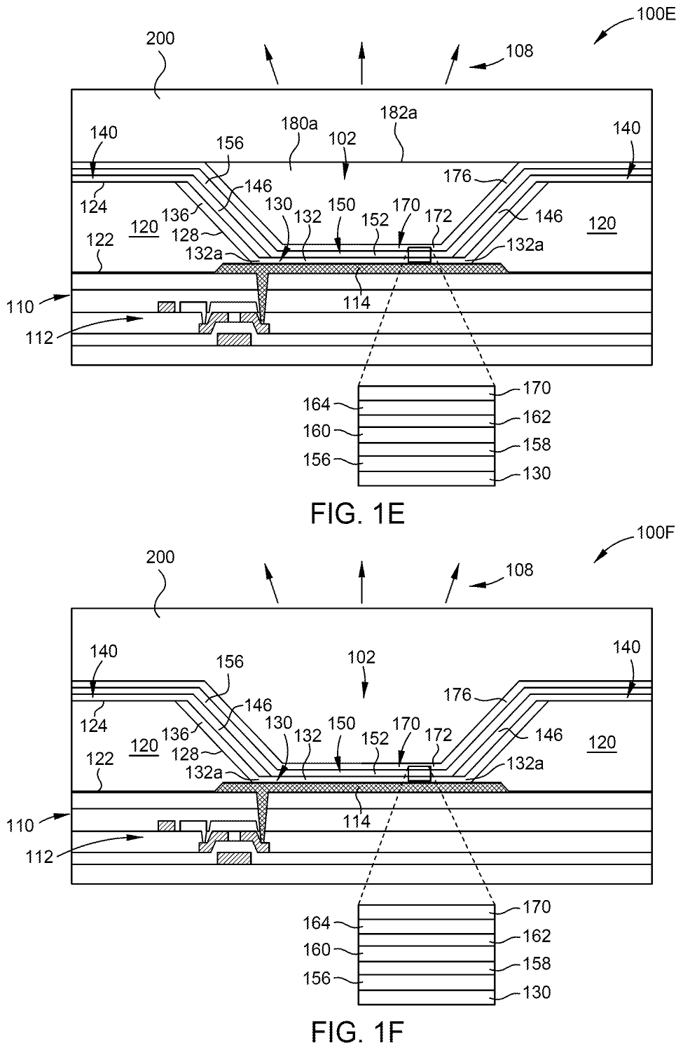

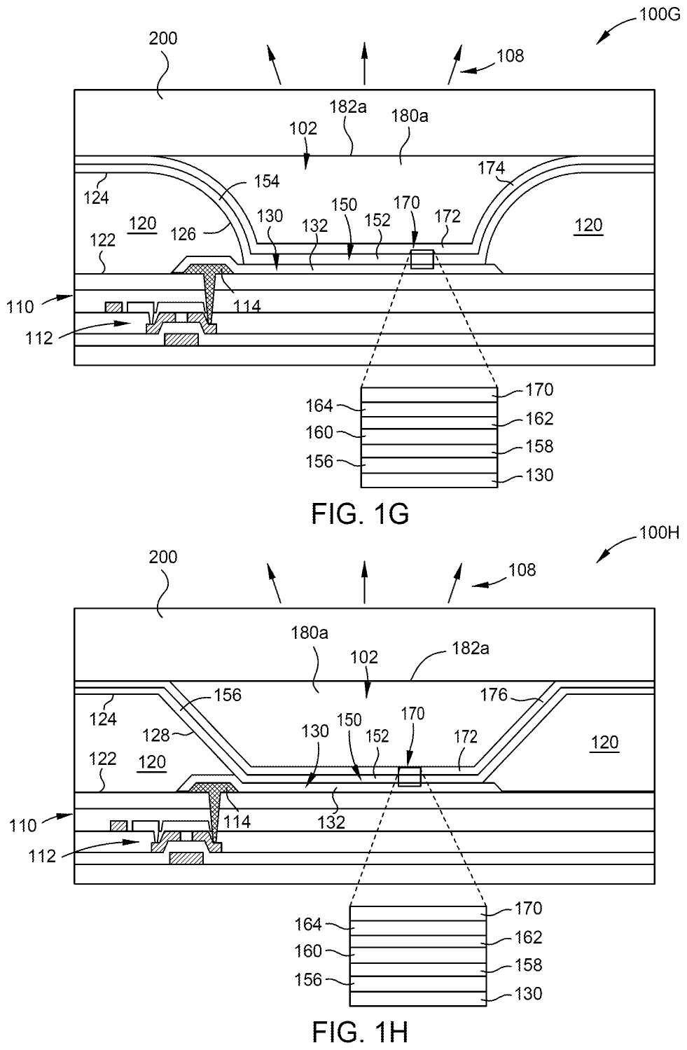

FIG. 1A is a schematic, top view of an array 10 of electroluminescent (EL) devices 100, according to one or more embodiments. The array 10 is formed on a substrate 110. In some embodiments, the EL devices 100 are OLED display pixels, and the array 10 is a top-emitting active matrix OLED display (top-emitting AMOLED) structure. In some embodiments, a width 104 and a length 106 of the EL devices 100 may be from about 2 μm or less up to about 200 μm. In one or more embodiments, the EL devices 100 include quantum-dot light-emitting diode (QD-LED) pixels, LED pixels, other self-emissive devices, or combinations thereof. Additional layers overlying the array 10 are omitted from FIG. 1A for clarity.

FIG. 1B is a schematic, side view of the array 10 of EL devices 100 of FIG. 1A, according to one or more embodiments. Here, the EL devices 100 (shown in phantom) are top-emitting and outcoupled light 108 exits the EL devices 100 from a top 109 thereof. A functional unit 200 is disposed over the array 10.

FIG. 1C is a schematic, side sectional view of an EL device 100C taken along section line 1-1 of FIG. 1A, where the EL device 100C has a graded reflective bank portion 134 and a patterned filler 180a. FIG. 1D is a schematic, side sectional view of another EL device 100D taken along section line 1-1 of FIG. 1A, where the EL device 100D has the graded reflective bank portion 134 and a non-patterned filler 180b.

The EL device 100 generally includes the substrate 110, a pixel definition layer (PDL) 120, a bottom reflective electrode layer 130, a dielectric layer 140, an organic layer 150, where the organic layer 150 is a multi-layer stack including a plurality of organic layers, a top electrode 170, and a filler 180a, b. In some embodiments, the substrate 110 may be formed from one or more of a silicon, glass, quartz, plastic, or metal foil material. In some embodiments, the substrate 110 may include a plurality of device layers (e.g., buffer layers, interlayer dielectric layers, insulating layers, active layers, and electrode layers). Here, a thin-film transistor (TFT) 112 is formed on the substrate 110. In some embodiments, an array of TFTs 112 may form a TFT driving circuit array configured to drive and control the array 10 of EL devices 100. However, the control circuit is not particularly limited to the illustrated embodiment. In some other embodiments, the control circuit includes complementary metal oxide semiconductor (CMOS) transistors. In some embodiments, the array 10 of EL devices 100 may be an OLED pixel array for a display. Here, an interconnection layer 114 is in electrical contact between the TFT 112 and the bottom reflective electrode layer 130. The EL device 100 electrically contacts the interconnection layer 114 via the bottom reflective electrode layer 130. In some embodiments, the EL device 100 includes a planarization layer (not shown) formed over the substrate 110.

The PDL 120 is disposed over the substrate 110. In some embodiments, a bottom surface 122 of the PDL 120 contacts the substrate 110, the interconnection layer 114, or both. The PDL 120 has a top surface 124 facing away from the substrate 110. An emission region 102 of the EL device 100 is formed by openings in the PDL 120 extending from the top surface 124 through to the bottom surface 122 of the PDL 120. The PDL 120 has graded sidewalls 126 (i.e., a graded bank) interconnecting the top and bottom surfaces 124, 122. Herein, graded is defined as being simple or compound curved. In some embodiments, the graded sidewalls 126 may have any non-linear profile. In some embodiments, the PDL 120 may be a photoresist formed from any suitable photosensitive organic or polymer-containing material. In some other embodiments, the PDL 120 may be formed from SiO₂, SiNₓ, SiON, SiCON, SiCN, Al₂O₃, TiO₂, Ta₂O₅, HfO₂, ZrO₂, or another dielectric material.

The bottom reflective electrode layer 130 (e.g., anode in standard top-emitting OLED configuration) includes a planar electrode portion 132 disposed over the interconnection layer 114 and a graded reflective portion 134 disposed over the graded sidewalls 126 of the PDL 120. Here, the graded portion 134 connects to the opposed lateral ends 132a of the planar portion 132. In some embodiments, the bottom reflective electrode layer 130 may be conformal to the interconnection layer 114 and the graded sidewalls 126. In some embodiments, the bottom reflective electrode layer 130 may extend to the top surface 124 of the PDL 120. In some embodiments, the bottom reflective electrode layer 130 may be a monolayer. In some other embodiments, the bottom reflective electrode layer 130 may be a multi-layer stack. In some embodiments, the bottom reflective electrode layer 130 may include a transparent conductive oxide layer and a metal reflective film. In some embodiments, the transparent conductive oxide layer may include one or more of indium tin oxide (ITO), indium zinc oxide (IZO), zinc oxide (ZnO), indium oxide (In₂O₃), indium gallium oxide (IGO), aluminum zinc oxide (AZO), gallium zinc oxide (GZO), combinations thereof, and multi-layer stacks thereof. In some embodiments, the metal reflective film may include one or more of aluminum (Al), silver (Ag), magnesium (Mg), platinum (Pt), lead (Pd), gold (Au), nickel (Ni), neodymium (Nd), iridium (Ir), chromium (Cr), Al:Ag alloys, other alloys thereof, other suitable metals and their alloys, combinations thereof, and multi-layer stacks thereof. In some other embodiments, the bottom reflective electrode layer 130 may include a transparent conductive oxide layer and a Distributed Bragg Reflector (DBR) including alternately stacked high refractive index and low refractive index material layers forming a reflective multi-layer. In yet other embodiments, the transparent conductive oxide may be combined with one or more of a metal, transparent conductive metal oxide, transparent dielectric, scattering reflector, DBR, other suitable material layers, combinations thereof, and multi-layer stacks thereof.

In some embodiments, the bottom reflective electrode layer 130 may directly contact the interconnection layer 114 and the PDL 120. Here, the planar electrode portion 132 and the graded reflective portion 134 are formed of the same material. In some other embodiments, the interconnection layer 114 forms the planar electrode portion 132 of the bottom reflective electrode layer 130. In such embodiments, the planar electrode portion 132 and the graded reflective portion 134 may be formed from different materials. For example, the planar electrode portion 132 may be a multi-layer stack of ITO/Ag/ITO, and the graded reflective portion 134 may be a scattering reflector, DBR, or metal alloy.

One advantage of the bottom reflective electrode layer 130 having the graded bank structure is that the curved slope of the graded portion 134 is easier to fabricate compared to an analogous straight bank structure having a constant slope. In some aspects, the graded slope of the bottom reflective electrode layer 130 is analogous to a composition of straight bank structures having different slopes at different positions. In that regard, another advantage of the graded bank structure is averaging of redirection effects of different bank angles producing a more uniform emission pattern. Another advantage of the graded bank structure is that, relative to the straight bank structure, the graded slope produces angular intensities closer to the Lambertian distribution.

The dielectric layer 140 includes a graded portion 144 disposed over the graded portion 134 of the bottom reflective electrode layer 130. Here, the dielectric layer 140 terminates at the planar portion 132 of the bottom reflective electrode layer 130 without extending over the planar portion 132. In some other embodiments, the dielectric layer 140 may overlap the opposed lateral ends 132a of the planar portion 132 without extending over the entire planar portion 132. In some embodiments, the dielectric layer 140 may extend laterally beyond the graded portion 134 of the bottom reflective electrode layer 130 to the top surface 124 of the PDL 120. In some embodiments, the dielectric layer 140 may directly contact the bottom reflective electrode layer 130 and/or the PDL 120. In some embodiments, the dielectric layer 140 may be conformal to the bottom reflective electrode layer 130 and/or the PDL 120. In some embodiments, the dielectric layer 140 may include any suitable low-k dielectric material. In some embodiments, the dielectric layer 140 may be formed from SiO₂, SiNₓ, SiON, SiCON, SiCN, Al₂O₃, TiO₂, Ta₂O₅, HfO₂, ZrO₂, or another dielectric material.

The organic layer 150 includes a planar portion 152 disposed over the planar portion 132 of the bottom reflective electrode layer 130 and a graded portion 154 disposed over the graded portion 144 of the dielectric layer 140. Here, the graded portion 154 connects to lateral ends of the planar portion 152. In some embodiments, the organic layer 150 may directly contact the bottom reflective electrode layer 130 and the dielectric layer 140. In some embodiments, the organic layer 150 may be conformal to the bottom reflective electrode layer 130 and the dielectric layer 140. In some embodiments, the organic layer 150 may extend laterally beyond the bottom reflective electrode layer 130, may extend over the top surface 124 of the PDL 120, or both. Here, the organic layer 150 includes a plurality of organic layers, namely a hole injection layer (HIL) 156, a hole transport layer (HTL) 158, an emissive layer (EML) 160, an electron transport layer (ETL) 162, and an electron injection layer (EIL) 164. However, the organic layer 150 is not particularly limited to the illustrated embodiment. For example, in another embodiment, one or more layers may be omitted from the organic layer 150. In yet another embodiment, one or more additional layers may be added to the organic layer 150. In yet another embodiment, the organic layer 150 may be inverted such that the plurality of layers are reversed.

The top electrode 170 (e.g., cathode in standard top-emitting OLED configuration) includes a planar portion 172 disposed over the planar portion 152 of the organic layer 150 and a graded portion 174 disposed over the graded portion 154 of the organic layer 150. Here, the graded portion 174 connects to opposed lateral ends of the planar portion 172. In some embodiments, the top electrode 170 may directly contact the organic layer 150. In some embodiments, the top electrode 170 may be conformal to the organic layer 150. In some embodiments, the top electrode 170 may extend laterally beyond the organic layer 150, may contact the dielectric layer 140, and/or may extend over the top surface 124 of the PDL 120. In some embodiments, the top electrode 170 may be a monolayer. In some other embodiments, the top electrode 170 may be a multi-layer stack. In some embodiments, the top electrode 170 may be formed from one or more of Al, Ag, Mg, Pt, Pd, Au, Ni, Nd, Ir, Cr, Li, LiF, Al:Ag alloys, Mg:Ag alloys, other alloys thereof, other suitable metals and their alloys, ITO, IZO, ZnO, In₂O₃, IGO, AZO, GZO, combinations thereof, and multi-layer stacks thereof. In some embodiments, the top electrode 170 may include an underlayer formed from one or more of HATCN, LiF, combinations thereof, or multi-layer stacks thereof. In some embodiments, the top electrode 170 may have a thickness of from about 5 nm to about 120 nm, such as from about 5 nm to about 50 nm, such as from about 10 nm to about 30 nm, such as about 20 nm, alternatively from about 50 nm to about 120 nm, such as from about 80 nm to about 120 nm, such as from about 90 nm to about 110 nm, such as about 100 nm.

The filler 180a, b is disposed over the top electrode 170. In some embodiments, the filler 180a, b may directly contact the top electrode 170. As illustrated in FIG. 1C, the filler 180a is patterned such that the filler 180a is disposed in the emission region 102 without extending from the opening where the EL device 100 is formed and over the adjacent the top surface 124 of the PDL 120. In other words, the filler 180a is selectively deposited, selectively etched, or both to confine the filler 180a only to the generally concave opening formed in the PDL 120, the concave opening being defined by the bottom surface 122 and the graded sidewalls 126. Here, an exposed surface 182a of the filler 180a is planar. However, the filler 180a, b is not particularly limited to the illustrated embodiment. For example, in some other embodiments, the filler 180a may be curved. When comparing an ITO top electrode having a patterned filler to a Mg:Ag alloy top electrode having a patterned filler, next has been shown to have a resultant improvement of about 30%. However, when comparing an ITO top electrode having a non-patterned filler to a Mg:Ag alloy top electrode having a non-patterned filler, next has only shown resultant improvement of about 5%. Thus, the improvement in efficiency is more pronounced for EL devices 100C having a patterned filler.

In another embodiment, e.g., illustrated in FIG. 1D, the filler 180b is non-patterned such that the filler 180b extends over the top surface 124 of the PDL 120 outside the emission region 102. In such embodiments, the filler 180b may extend laterally beyond the top electrode 170, may contact the dielectric layer 140, or both. One advantage of the non-patterned filler 180b is that, without patterning, the filler 180b is easier, and thus less expensive, to fabricate. On the other hand, one advantage of the patterned filler 180a is improved external optical outcoupling efficiency from the EL device 100C compared to the EL device 100D. This may be due, at least in part, to reduced lateral waveguided light leakage in the reduced thickness patterned filler 180a.

In some embodiments, the filler 180a, b may include one or more high refractive index materials (i.e., n≥1.8), or index-matching materials, having a similar refractive index to the emission region 102. In some embodiments, the refractive index of the filler 180a, b, may exceed the refractive index of the emission region 102 by about 0.2 or more. In one or more embodiments, the filler 180a, b may be highly transparent. For example, the filler 180a, b can include one or more metal oxides, metal nitrides, Al₂O₃, SiO₂, TiO, TaO, AlN, SiN, SiOₓNₓ, TiN, TaN, high refractive index nanoparticles, other suitable materials, and combinations thereof. Non-limiting examples of materials that can be used in the filler 180a, b include any suitable material that can be integrated into OLED fabrication, such as organic materials (e.g., N,N′-Bis(napthalen-1-yl)-N,N′-bis(phenyl)benzidine, or NPB), inorganic materials, resins, or a combination thereof. The filler 180a, b can include a composite such as a colloidal mixture where the colloids are high refractive index inorganic materials such as TiO₂.

A functional unit 200 is disposed over the EL device 100C. The functional unit 200 includes one or more material layers disposed over the EL device 100C. In one or more embodiments, the functional unit 200 includes a stack of thin film encapsulation (TFE) layers. In some embodiments, the functional unit 200 includes a dielectric layer disposed between the EL device 100C and the TFE stack. In some other embodiments, the functional unit 200 includes a spatial optical differentiator, e.g., a Distributed Bragg Reflector (DBR), disposed above the dielectric layer, below the dielectric layer, or between the TFE stack and the EL device 100C, when the dielectric layer is omitted. Various different embodiments and aspects of the functional unit 200 are described in more detail below.

FIG. 1E is a schematic, side sectional view of an EL device 100E taken along section line 1-1 of FIG. 1A, where the EL device 100E has a straight reflective bank portion 136 and the patterned filler 180a. The EL device 100E is similar to the EL device 100C except as otherwise described below.

Here, the PDL 120 has straight sidewalls 128 (i.e., a straight bank) interconnecting the top and bottom surfaces 124, 122. Herein, straight is defined as being substantially linear. Here, the bottom reflective electrode layer 130 includes the planar electrode portion 132 disposed over the interconnection layer 114 and a straight reflective bank portion 136 disposed over the straight sidewalls 128 of the PDL 120. Here, the dielectric layer 140 includes a straight bank portion 146 disposed over the straight reflective bank portion 136 of the bottom reflective electrode layer 130. Here, the organic layer 150 includes the planar portion 152 disposed over the planar portion 132 of the bottom reflective electrode layer 130 and a straight bank portion 156 disposed over the straight bank portion 146 of the dielectric layer 140. Here, the top electrode 170 includes the planar portion 172 disposed over the planar portion 152 of the organic layer 150 and a straight bank portion 176 disposed over the straight bank portion 156 of the organic layer 150.

FIG. 1F is a schematic, side sectional view of another EL device 100F taken along section line 1-1 of FIG. 1A, where the EL device 100F has the straight reflective bank portion 136 without the filler 180a, b. The EL device 100F is similar to the EL device 100E except as otherwise described below. Here, the filler 180a, b is omitted such that the top electrode 170 interfaces with air.

FIG. 1G is a schematic, side sectional view of another EL device 100G taken along section line 1-1 of FIG. 1A, where the graded reflective bank portion 134 and the dielectric layer 140 are omitted from the EL device 100G. The EL device 100G is similar to the EL device 100C except as otherwise described below. Here, the bottom reflective electrode layer 130 includes the planar electrode portion 132 disposed on the substrate 110, coupling to the interconnection layer 114, and underlying the PDL 120. Here, the organic layer 150 includes the planar portion 152 disposed over the planar portion 132 of the bottom reflective electrode layer 130 and the graded bank portion 154 disposed over the graded sidewalls 126 of the PDL 120.

In some embodiments, the PDL 120 has a refractive index that is about 1.6 or less, such as from about 1.0 to about 1.4, such as from about 1.1 to about 1.3 at a wavelength or wavelength range of the light emitted from the electroluminescent area (e.g., UV, near infrared, and visible, such as about 380 nm to about 780 nm). In at least one embodiment, the PDL 120 has a refractive index (n) that is or ranges from n₁ to n₂ at a wavelength or wavelength range of the light emitted from the electroluminescent area, where each of n₁ and n₂ is independently about 1.0, about 1.1, about 1.2, about 1.3, about 1.4, about 1.5, or about 1.6, so long as n₂>n₁. In some embodiments, the filler 180a has a refractive index that is about 1.6 or more, such as from about 1.8 to about 2.4, such as from about 1.8 to about 1.9, from about 1.9 to about 2.0, or from about 2.0 to about 2.2 at a wavelength or wavelength range of the light emitted from the electroluminescent area (e.g., UV, near infrared, and visible, such as about 380 nm to about 780 nm). In at least one embodiment, the filler 180a has a refractive index that is or ranges from n₅ to n₆ at a wavelength or wavelength range of the light emitted from the electroluminescent area, where each of n₅ and n₆ is independently about 1.6, about 1.7, about 1.8, about 1.9, about 2.0, about 2.1, about 2.2, about 2.3, about 2.4, or about 2.5, so long as n₆>n₅. In some embodiments, where the refractive index of the PDL 120 is less than the refractive index of the filler 180a, light traveling from higher to lower refractive index can undergo total internal reflection. This effect, at certain critical angles, can create a reflective interface without using the graded reflective bank portion 134 of the bottom reflective electrode layer 130.

FIG. 1H is a schematic, side sectional view of another EL device 100H taken along section line 1-1 of FIG. 1A, where the straight reflective bank portion 136 and the dielectric layer 140 are omitted from the EL device 100H. The EL device 100H is similar to the EL device 100G except as otherwise described below. Here, the PDL 120 has straight sidewalls 128 (i.e., a straight bank) interconnecting the top and bottom surfaces 124, 122. Here, the organic layer 150 includes the planar portion 152 disposed over the planar portion 132 of the bottom reflective electrode layer 130 and the straight bank portion 156 disposed over the straight sidewalls 128 of the PDL 120. Here, the top electrode 170 includes the planar portion 172 disposed over the planar portion 152 of the organic layer 150 and the straight bank portion 176 disposed over the straight bank portion 156 of the organic layer 150.

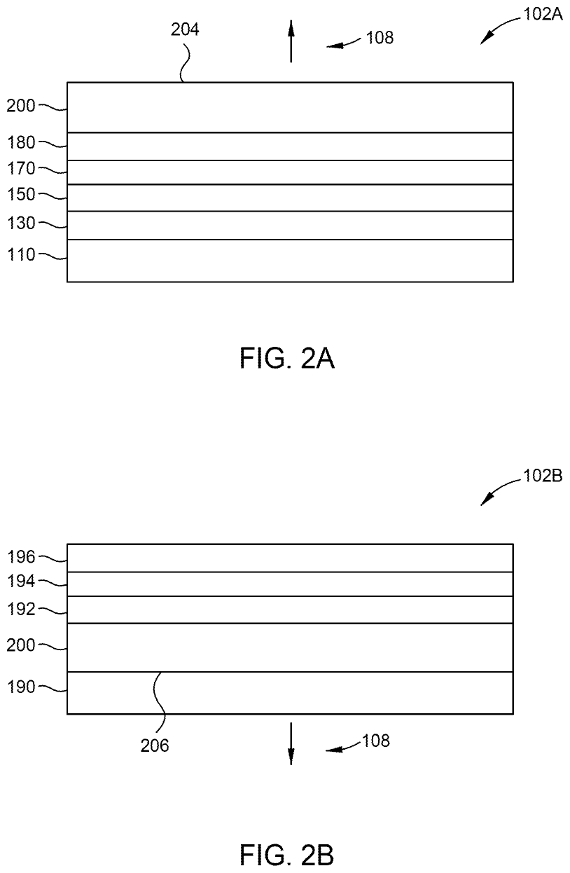

FIG. 2A is a schematic diagram of an emission region 102A of a top-emitting EL device. The emission region 102A includes the substrate 110, the bottom reflective electrode layer 130, the organic layer 150, where the organic layer 150 is a multi-layer stack including a plurality of organic layers, the top electrode 170, and the filler 180. The functional unit 200 is disposed on top of and over the filler 180 in the emission region 102A. Emitted light 108 exits the emission region 102A through a top surface 204 of the functional unit 200. FIG. 2B is a schematic diagram of an emission region 102B of a bottom-emitting EL device. The emission region 102B includes a semi-transparent substrate 190, the functional unit 200, a transparent bottom electrode 192, an organic layer 194, and a reflective top electrode 196. The functional unit 200 is disposed between the semi-transparent substrate 190 and the transparent bottom electrode 192. In the bottom-emitting EL device, the functional unit 200 includes one or more layers formed on the substrate 190 including a planar layer, an isolation layer, other layers, or combinations thereof. Emitted light 108 exits the emission region 102B through a bottom surface 206 of the functional unit 200 facing the substrate 190.

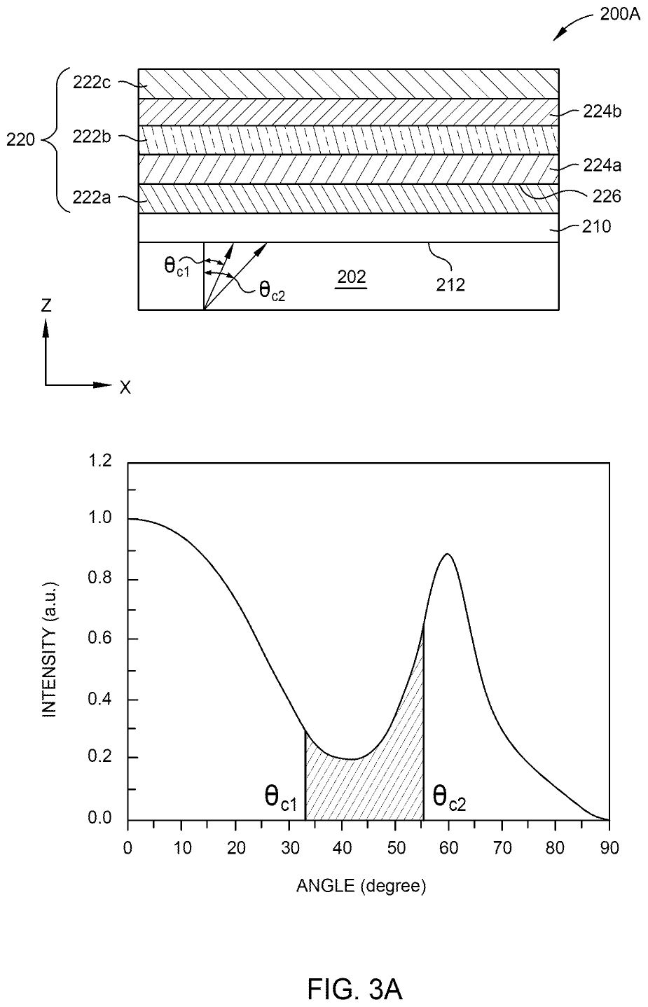

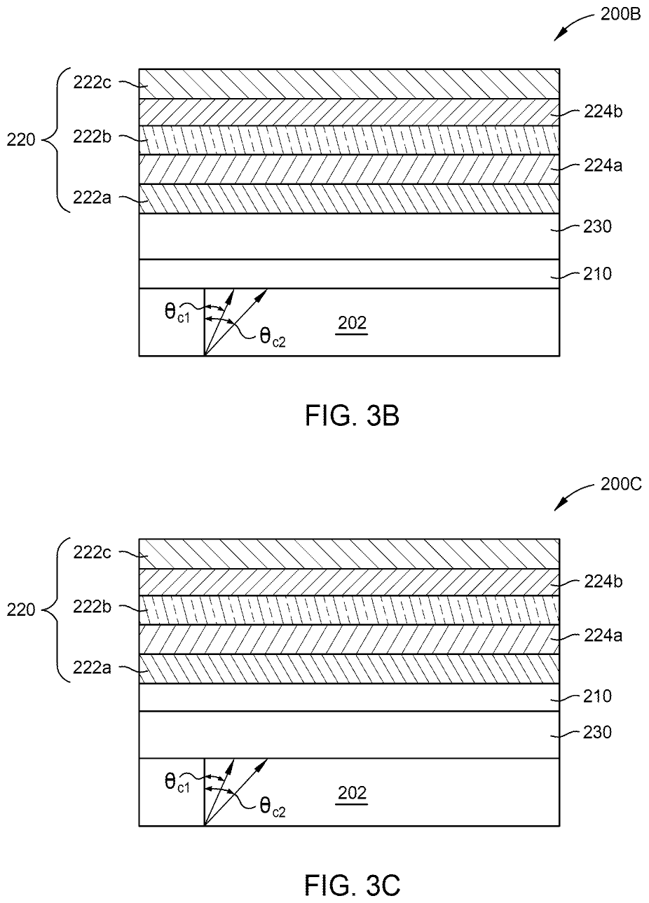

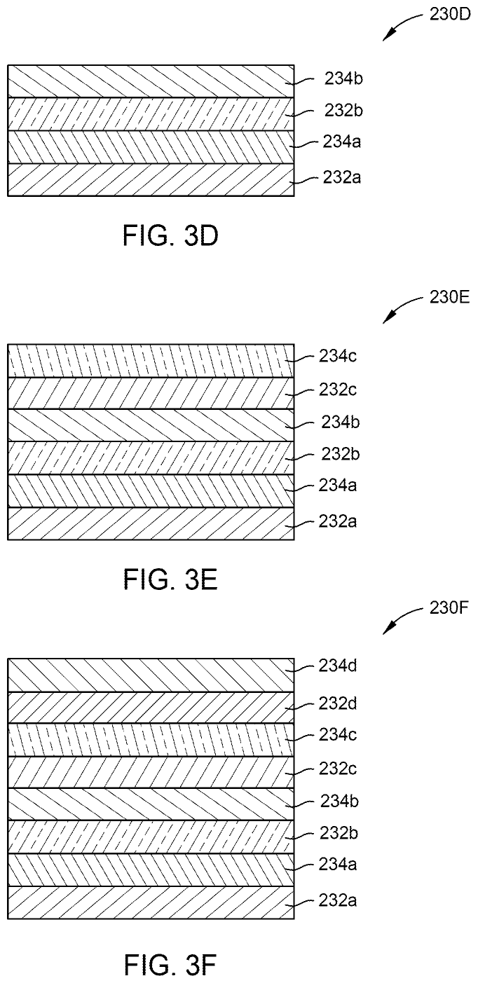

FIG. 3A is a schematic, side sectional view of a functional unit 200A including a dielectric layer 210 underlying a TFE stack 220. The functional unit 200 is disposed over an EL device pixel 202. The EL device pixel 202 underlying the dielectric layer 210 can correspond to EL devices 100C-100H, aspects thereof, or combinations thereof without limitation.

The dielectric layer 210 is disposed on the filler 180a, b. In some embodiments, the dielectric layer 210 is formed from SiO₂, another dielectric material, or combinations thereof. In some embodiments, a thickness of the dielectric layer 210 is from about 20 nm to about 2 μm, such as from about 0.2 μm to about 2 μm, such as from about 0.2 μm to about 1 μm, such as from about 0.4 μm to about 0.6 μm, such as about 0.5 μm. In some embodiments, the dielectric layer 210 has a refractive index of about 1.8 or less, such as from about 1.3 to about 1.7, such as from about 1.4 to about 1.6, such as about 1.5.

The TFE stack 220 includes alternating layers of polymer and dielectric materials. Here, the TFE stack 220 includes a first dielectric layer 222a disposed on the dielectric layer 210. Above the first dielectric layer 222a, the TFE stack 220 sequentially includes a first polymer layer 224a, a second dielectric layer 222b, a second polymer layer 224b, and a third dielectric layer 222c. However, the TFE stack 220 is not particularly limited to the illustrated embodiment. In some other embodiments, the TFE stack 220 includes only the first dielectric layer 222a, the first polymer layer 224a, and the second dielectric layer 222b.

In some embodiments, the dielectric layers 222a-c of the TFE stack 220 are formed from SiNₓ, other dielectric materials, or combinations thereof. Here, the dielectric layers 222a-c of the TFE stack 220 are formed from the same material. In some other embodiments, one or more of the dielectric layers 222a-c of the TFE stack 220 are formed from different materials. In some embodiments, e.g., using chemical vapor deposition, thicknesses of the dielectric layers 222a-c of the TFE stack 220 are from about 0.5 μm to about 2 μm, such as from about 0.8 μm to about 1 μm, such as about 0.9 μm. In some other embodiments, e.g., using atomic layer deposition, thicknesses of the dielectric layers 222a-c of the TFE stack 220 are about 500 nm or less, such as from about 10 nm to about 50 nm. Here, the dielectric layers 222a-c of the TFE stack 220 have the same thickness. In some other embodiments, one or more of the dielectric layers 222a-c of the TFE stack 220 have different thicknesses. In some embodiments, the dielectric layers 222a-c of the TFE stack 220 have refractive indices of from about 1.7 to about 2, such as from about 1.8 to about 1.9, such as about 1.85. Here, the dielectric layers 222a-c of the TFE stack 220 have the same refractive index. In some other embodiments, one or more of the dielectric layers 222a-c of the TFE stack 220 have different refractive indices. In some embodiments, the refractive indices of the dielectric layers 222a-c of the TFE stack 220 are greater than the refractive index of the dielectric layer 210.

In some embodiments, the polymer layers 224a-b of the TFE stack 220 are formed from one or more organic materials, acrylic materials, other polymeric materials, or combinations thereof. Here, the polymer layers 224a-b of the TFE stack 220 are formed from the same material. In some other embodiments, one or more of the polymer layers 224a-b of the TFE stack 220 are formed from different materials. In some embodiments, thicknesses of the polymer layers 224a-b of the TFE stack 220 are from about 1 μm to about 15 μm, such as from about 5 μm to about 10 μm, such as about 8 μm. Here, the polymer layers 224a-b of the TFE stack 220 have the same thickness. In some other embodiments, one or more of the polymer layers 224a-b of the TFE stack 220 have different thicknesses. In some embodiments, the polymer layers 224a-b of the TFE stack 220 have refractive indices of about 1.8 or less, such as from about 1.3 to about 1.7, such as from about 1.4 to about 1.6, such as about 1.5. Here, the polymer layers 224a-b of the TFE stack 220 have the same refractive index. In some other embodiments, one or more of the polymer layers 224a-b of the TFE stack 220 have different refractive indices. In some embodiments, the refractive indices of the polymer layers 224a-b of the TFE stack 220 are about equal to the refractive index of the dielectric layer 210.

One advantage of the functional unit 200A including the dielectric layer 210 underlying the TFE stack 220 is improved outcoupling efficiency. In particular, with the dielectric layer 210 included, an interface 212 between the dielectric layer 210 and the EL device pixel 202 (e.g., the filler 180a, b thereof) is located closer to the 3D pixel configuration of the EL device pixel 202 compared to the same functional unit without the dielectric layer 210. Having the interface 212, e.g., a total internal reflection (TIR) interface, positioned closer to the 3D pixel configuration improves outcoupling. Without the dielectric layer 210, substantial light reflection occurs at an interface 226 between the first dielectric layer 222a and the first polymer layer 224a due to the difference in refractive index between the layers 222a, 224a. Without the dielectric layer 210, significant loss of outcoupling efficiency occurs at the interface 226, e.g., about 14% efficiency loss. However, addition of the dielectric layer 210 reduces the loss of outcoupling efficiency at the interface 226, e.g., to less than 5% efficiency loss. This improvement in efficiency at the interface 226 results in improved outcoupling efficiency from the functional unit 200A overall.

Outcoupling of light from the EL device pixel 202 is at least partially dependent on the angle of light incident upon the functional unit 200A, where the angle is measured relative to the z-axis. In some embodiments, light with an incident angle of θ_{c1} or less (e.g., low-angle light) is extracted directly, light with an incident angle of θ_{c2} or more (e.g., high-angle light) is confined to the EL device pixel 202 (e.g., the filler 180a, b thereof) and extracted by the 3D pixel configuration of the EL device pixel 202, and light with an incident angle between θ_{c1} and θ_{c2} (e.g., mid-angle light) is lost, e.g., by being trapped in the functional unit 200A. Here, θ_{c1} is a simulated critical angle between the filler 180a, b and air and θ_{c2} is a simulated critical angle at the interface 212. In some embodiments, the angle θ_{c1} is from about 25° to about 40°, such as from about 30° to about 35°, such as about 35°, and the angle θ_{c2} is from about 50° to about 60°, such as about 55°. Referring to the right side of FIG. 3A, exemplary data demonstrating angular dependence of light extraction is illustrated by the plot of intensity vs. angle in degrees. Here, mid-angle light loss between θ_{c1} and θ_{c2} is much greater relative to the loss of low-angle and high-angle light.

In some embodiments, the dielectric layer 210 replaces the first dielectric layer 222a and provides the same function thereof with regard to the index and thickness effects. In one or more embodiments, the dielectric layer 210 provides encapsulation properties similar the first dielectric layer 222a.

FIG. 3B is a schematic, side sectional view of a functional unit 200B including a spatial optical differentiator 230 between the dielectric layer 210 and the TFE stack 220. The EL device pixel 202 can correspond to EL devices 100C-100H, aspects thereof, or combinations thereof without limitation. The dielectric layer 210 and the TFE stack 220 can correspond to the functional unit 200A, aspects thereof, or combinations thereof without limitation. Here the spatial optical differentiator 230 is disposed over the dielectric layer 210 and underlying the TFE stack 220. FIG. 3C is a schematic, side sectional view of a functional unit 200C including the spatial optical differentiator 230 between the EL device pixel 202 and the dielectric layer 210. The EL device pixel 202 can correspond to EL devices 100C-100H, aspects thereof, or combinations thereof without limitation. The dielectric layer 210 and the TFE stack 220 can correspond to the functional unit 200A, aspects thereof, or combinations thereof without limitation. Here the spatial optical differentiator 230 is disposed over the EL device pixel 202 (e.g., the filler 180a, b thereof) and underlying the dielectric layer 210.

In one or more embodiments, the spatial optical differentiator 230 is a Distributed Bragg Reflector (DBR), a photonic crystal, a meta-surface (e.g., dielectric meta-surfaces having a high-quality magnetic resonance mode that is hybridized with the classic bounded surface wave via grating coupling), other materials or structures that enable wavelength or incident angle dependent selective transmission and reflection, similar materials or structures, or combinations thereof. In some embodiments, the spatial optical differentiator 230 selectively reflects and/or transmits light based on the incident angle of light upon the functional unit 200A. In other words, the spatial optical differentiator 230 filters light based on the incident angle. The spatial optical differentiator 230 reflects light with an incident angle between θ_{c1} and θ_{c2} (e.g., mid-angle light) such that the reflected light is confined to the EL device pixel 202 (e.g., the filler 180a, b thereof) and extracted by the 3D pixel configuration of the EL device pixel 202. Similar to the EL device pixel 202 without the spatial optical differentiator 230, the spatial optical differentiator 230 transmits light with an incident angle of θ_{c1} or less (e.g., low-angle light). Likewise, similar to the EL device pixel 202 without the spatial optical differentiator 230, the spatial optical differentiator 230 reflects light with an incident angle of θ_{c2} or more (e.g., high-angle light) such that the reflected light is confined to the EL device pixel 202 (e.g., the filler 180a, b thereof) and extracted by the 3D pixel configuration of the EL device pixel 202. In some embodiments, the spatial optical differentiator 230 includes two or more pairs of alternating high refractive index layers and low refractive index layers, such as from 2 to 8 pairs of alternating high index-low index layers. In some embodiments, outcoupling efficiency is improved by having a higher number of high index-low index pairs. In some embodiments, outcoupling efficiency is improved by having a relatively larger difference in refractive index between the high index and low index layers. In some embodiments, outcoupling efficiency is at least partially dependent upon the thickness of each layer of the spatial optical differentiator 230.

In some embodiments, the spatial optical differentiator 230 replaces the dielectric layer 210, the first dielectric layer 222a, or both. In one or more embodiments, the spatial optical differentiator 230 provides the same function as the dielectric layer 210, the first dielectric layer 222a, or both with regard to the index and thickness effects. In one or more embodiments, the spatial optical differentiator 230 provides encapsulation properties similar to the dielectric layer 210, the first dielectric layer 222a, or both. In some embodiments, either of the dielectric layer 210 or the spatial optical differentiator 230 can be positioned between layers of the TFE stack 220 or above or below the TFE stack 220 without limitation.

FIG. 3D is a schematic, side sectional view of a spatial optical differentiator 230D having 2 pairs of high index-low index layers. Here, the spatial optical differentiator 230D includes a first low refractive index layer 232a, a first high refractive index layer 234a thereabove, a second low refractive index layer 232b thereabove, and a second high refractive index layer 234b thereabove. The spatial optical differentiator 230D starts with the first low index layer 232a positioned closer to the EL device pixel 202 than the first high index layer 234a. However, the spatial optical differentiator 230D is not particularly limited to the illustrated embodiment. In some other embodiments, the order of the layers is reversed such that the first high index layer 234a is positioned closest to the EL device pixel 202.

FIG. 3E is a schematic, side sectional view of a spatial optical differentiator 230E having 3 pairs of high index-low index layers. The spatial optical differentiator 230E further includes a third low refractive index layer 232c and a third high refractive index layer 234c thereabove.

FIG. 3F is a schematic, side sectional view of a spatial optical differentiator 230F having 4 pairs of high index-low index layers. The spatial optical differentiator 230F further includes a fourth low refractive index layer 232d and a fourth high refractive index layer 234d thereabove.

In some embodiments, the spatial optical differentiator 230 is formed using a dielectric or inorganic process which can be integrated with the fabrication of the TFE stack 220. In some embodiments, the low index layers 232 are formed from SiO₂, other dielectric materials, other inorganic materials, other similar materials, or combinations thereof. In one or more embodiments, the low index layers 232 have a refractive index of about 1.8 or less, such as about 1.6 or less, such as from about 1 to about 1.6, such as from about 1.4 to about 1.5, such as about 1.48. In one or more embodiments, a thickness of the low index layers 232 is about 50 nm or greater, such as from about 50 nm to about 500 nm, such as from about 50 nm to about 250 nm, such as from about 50 nm to about 150 nm, such as from about 90 nm to about 150 nm, such as from about 100 nm to about 125 nm.

In some embodiments, the high index layers 234 are formed from SiNₓ, TiO₂, other dielectric materials, other inorganic materials, other similar materials, or combinations thereof. In one or more embodiments, the high index layers 234 have a refractive index of about 1.8 or greater, such as from about 1.8 to about 2.5, such as from about 2 to about 2.45, such as about 2, alternatively about 2.45. The refractive index of the high index layers 234 is greater than the refractive index of the low index layers 232. In some embodiments, a difference in the refractive indices of the low index and high index layers 232, 234 is about 0.2 or greater, such as about 0.3 or greater, such as about 0.4 or greater, such as about 0.5 or greater, such as about 0.75 or greater, such as about 1 or greater, alternatively from about 0.2 to about 2, such as about 0.5 to about 1. In one or more embodiments, a thickness of the high index layers 234 is about 50 nm or greater, such as from about 50 nm to about 500 nm, such as from about 50 nm to about 250 nm, such as from about 50 nm to about 150 nm, such as from about 70 nm to about 120 nm, such as from about 70 nm to about 120 nm, such as from about 80 nm to about 100 nm. In embodiments using the dielectric process, each of the layers of the spatial optical differentiator 230 are formed using plasma enhanced chemical vapor deposition (PECVD), other similar deposition techniques, or combinations thereof.

In some other embodiments, the spatial optical differentiator 230 is formed using an organic process which can be integrated with the fabrication of the EL device pixel 202. In some embodiments, the low index layers 232 are formed from LiF, other similar materials, or combinations thereof. In one or more embodiments, the low index layers 232 have a refractive index of about 1.8 or less, such as about 1.6 or less, such as from about 1 to about 1.6, such as from about 1.3 to about 1.4, such as about 1.37. In some embodiments, the high index layers 234 are formed from NPB, other organic materials, other similar materials, or combinations thereof. In one or more embodiments, the high index layers 234 have a refractive index of about 1.8 or greater, such as from about 1.8 to about 2.5, such as from about 1.8 to about 2, such as about 1.83. In some embodiments using the organic process, the dielectric layer 210 is omitted. In embodiments using the organic process, each of the layers of the spatial optical differentiator 230 are formed using high-vacuum thermal deposition, other suitable deposition techniques, or combinations thereof. In some embodiments using the organic process, a thickness of the first dielectric layer 222a is from about 100 nm to about 200 nm, such as about 130 nm. Using a thinner first dielectric layer 222a moves the reflective interface 226 closer to the bottom reflective electrode layer 130 resulting in improved outcoupling efficiency, e.g. by about 5% or more, relative to a thicker first dielectric layer 222a having a thickness of about 900 nm.

In some embodiments, the spatial optical differentiator 230 improves outcoupling efficiency by about 10% or more relative to the same functional unit 200 without the spatial optical differentiator 230. One advantage of using the functional units 200A-C described herein is improved outcoupling efficiency from the EL device pixel 202. In turn, higher efficiency improves lifetime of the device, providing the same brightness at lower power and longer one-time charge usage of mobile devices.

### Example Distributed Bragg Reflector (DBR) Structures

As described above, spatial optical differentiators 230 disclosed herein may be implemented in the form of DBR structures. DBR structures may provide nearly 100% reflectance around a target wavelength (λ_{T}) at normal incidence and may form a near perfect reflection band. In contrast, away from the reflection band, the reflectivity of DBR pairs may be extremely low (e.g., near zero). In some examples, DBR structures may have λ_{T} within a range of about 600 nm to about 1,100 nm, such as 600 nm, 700 nm, 800 nm, 900 nm, 1,000 nm, or 1,100 nm. Parameters for DBR structures with various different λ_{T} listed above are detailed in Table 1. In this example, the DBR structures may include from 2 to 4 pairs of high-index and low-index material layers. In this example, the high-index material in each pair is NPB (n_{NPB}˜1.84 at 520 nm), and the low-index material in each pair is LiF (n_{LIF}˜1.37 at 520 nm). In this example, the first TFE layer corresponds to the first dielectric layer 222a of the TFE stack 220 shown in FIGS. 3B-3C. In this example, the first TFE layer may be part of the DBR structure. Therefore, the thickness of the first TFE layer is adjusted according to λ_{T}. As shown in Table 1, the thickness of each layer in the DBR structure is dependent on selected λ_{T}.

TABLE 1

| | NPB | LiF | First TFE |
|---|---|---|---|
| λ_{T} | Thickness | Thickness | Layer |
| (nm) | (nm) | (nm) | Thickness (nm) |
| 600 | 82 | 110 | 79 |
| 700 | 95 | 128 | 92 |
| 800 | 109 | 146 | 105 |
| 900 | 123 | 165 | 118 |
| 1,000 | 136 | 183 | 131 |
| 1,100 | 150 | 201 | 144 |

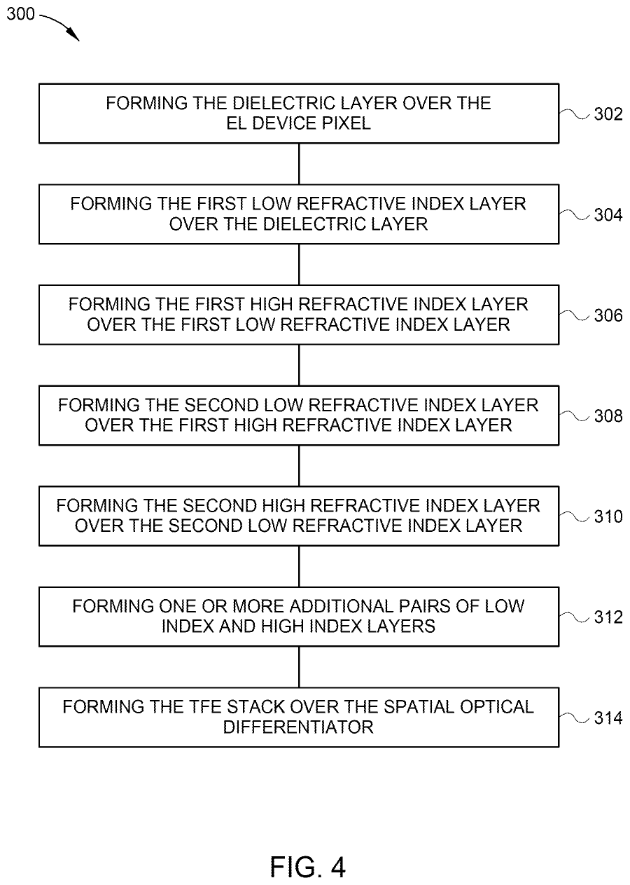

FIG. 4 is a diagram illustrating a method 300 for fabricating a functional unit 200 for an EL device pixel 202, where the dielectric layer 210 is formed between the EL device pixel 202 and the spatial optical differentiator 230. Referring to FIGS. 3B and 3D, at operation 302 the dielectric layer 210 is formed over the EL device pixel 202 (e.g., the filler 180a, b thereof). At operation 304, the first low refractive index layer 232a is formed over the dielectric layer 210. At operation 306, the first high refractive index layer 234a is formed over the first low refractive index layer 232a. At operation 308, the second low refractive index layer 232b is formed over the first high refractive index layer 234a. At operation 310, the second high refractive index layer 234b is formed over the second low refractive index layer 232b. At operation 312, one or more additional pairs of low index and high index layers are formed. At operation 314, the TFE stack 220 is formed over the spatial optical differentiator 230.

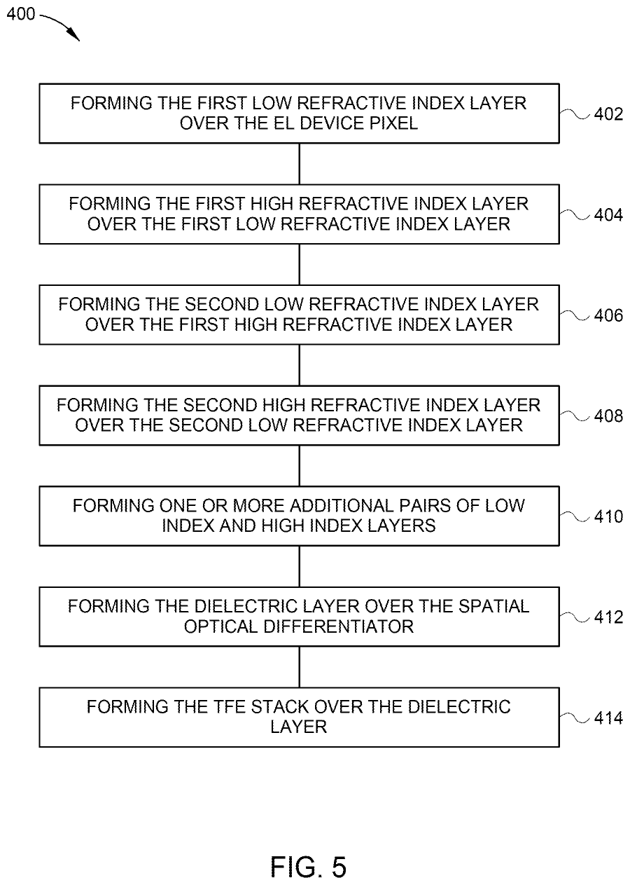

FIG. 5 is a diagram illustrating a method 400 for fabricating another functional unit 200 for an EL device pixel 202, where the dielectric layer 210 is formed between the spatial optical differentiator 230 and the TFE stack 220. Referring to FIGS. 3C and 3D, at operation 402, the first low refractive index layer 232a is formed over the EL device pixel 202 (e.g., a filler 180a, b thereof). At operation 404, the first high refractive index layer 234a is formed over the first low refractive index layer 232a. At operation 406, the second low refractive index layer 232b is formed over the first high refractive index layer 234a. At operation 408, the second high refractive index layer 234b is formed over the second low refractive index layer 232b. At operation 410, one or more additional pairs of low index and high index layers are formed. At operation 412, the dielectric layer 210 is formed over the spatial optical differentiator 230. At operation 414, the TFE stack 220 is formed over the dielectric layer 210.

In some embodiments, the orientation of high index and low index layers is reversed. In one or more embodiments, forming the layers of the spatial optical differentiator 230 and forming the TFE stack 220 use the same process such that the process of forming the spatial optical differentiator 230 is integrated with the process of forming the TFE stack 220. In one or more embodiments, forming the layers of the spatial optical differentiator 230 includes using a dielectric process. In one or more embodiments, the dielectric process includes PECVD. In one or more other embodiments, forming the layers of the spatial optical differentiator includes using an organic process. In some embodiments, the organic process is integrated with fabrication of the EL device pixel 202. In one or more embodiments, the organic process includes high-vacuum thermal deposition. In one or more embodiments, forming the dielectric layer 210 is omitted from the methods 300, 400.

While the foregoing is directed to examples of the present disclosure, other and further examples of the disclosure may be devised without departing from the basic scope thereof, and the scope thereof is determined by the claims that follow.

What is claimed is:

1. A functional unit for an electroluminescent (EL) device pixel, the functional unit comprising:
a spatial optical differentiator disposed adjacent the EL device pixel, wherein the spatial optical differentiator is configured to selectively reflect and transmit light based on an incident angle of light upon the functional unit.

2. The functional unit of claim 1, further comprising a thin film encapsulation (TFE) stack disposed over the spatial optical differentiator.

3. The functional unit of claim 2, wherein the spatial optical differentiator is a Distributed Bragg Reflector (DBR).

4. The functional unit of claim 3, wherein the DBR comprises alternating layers having high refractive index and low refractive index, and wherein the DBR comprises from 2 or more pairs of alternating layers.

5. The functional unit of claim 4, wherein the high refractive index exceeds the low refractive index by about 0.2 or more.

6. The functional unit of claim 2, further comprising a dielectric layer disposed between the spatial optical differentiator and the TFE stack.

7. The functional unit of claim 2, further comprising a dielectric layer disposed between a filler of the EL device pixel and the spatial optical differentiator.

8. The functional unit of claim 1, wherein the EL device is bottom-emitting, and wherein the functional unit further comprises at least one of a planar layer or an isolation layer disposed under the spatial optical differentiator.

9. A method of fabricating a functional unit for an electroluminescent (EL) device pixel, the method comprising:
forming a first layer of a spatial optical differentiator adjacent the EL device pixel, the first layer having a first refractive index;
forming a second layer of the spatial optical differentiator over the first layer, the second layer having a second refractive index, wherein a difference between the first and second refractive indices is about 0.2 or greater;
forming a third layer of the spatial optical differentiator over the second layer, the third layer having the first refractive index; and
forming a fourth layer of the spatial optical differentiator over the third layer, the fourth layer having the second refractive index, wherein the spatial optical differentiator is configured to selectively reflect and transmit light based on an incident angle of light upon the functional unit.

10. The method of claim 9, wherein the EL device is top-emitting, further comprising forming a thin film encapsulation (TFE) stack over the spatial optical differentiator.

11. The method of claim 10, further comprising forming a dielectric layer between the spatial optical differentiator and the TFE stack.

12. The method of claim 10, further comprising forming a dielectric layer between a filler of the EL device pixel and the first layer of the spatial optical differentiator.

13. The method of claim 10, wherein forming the layers of the spatial optical differentiator and forming the TFE stack comprises the same process.

14. The method of claim 9, wherein forming the layers of the spatial optical differentiator comprises a dielectric process, and wherein the dielectric process includes plasma enhanced chemical vapor deposition.

15. The method of claim 9, wherein forming the layers of the spatial optical differentiator comprises an organic process, wherein the organic process is integrated with fabrication of the EL device pixel, and wherein the organic process includes high-vacuum thermal deposition.

16. The method of claim 9, further comprising forming one or more additional first and second refractive index layer pairs.

17. The method of claim 9, wherein the EL device is bottom-emitting, and wherein the spatial optical differentiator is formed over at least one of a planar layer or an isolation layer of the functional unit.

18. A display structure, comprising:
an array of electroluminescent (EL) device pixels;
a functional unit disposed adjacent the array of EL device pixels, the functional unit comprising:
a spatial optical differentiator disposed adjacent the EL device pixel, wherein the spatial optical differentiator is configured to selectively reflect and transmit light based on an incident angle of light upon the functional unit;
a plurality of thin-film transistors forming a driving circuit array configured to drive and control the array of EL device pixels; and
a plurality of interconnection layers, each interconnection layer in electrical contact between an EL pixel and a respective thin-film transistor of the plurality of thin-film transistors.

19. The display structure of claim 18, wherein the EL device pixels are top-emitting, and wherein the functional unit further comprises a thin film encapsulation (TFE) stack disposed over the spatial optical differentiator.

20. The display structure of claim 18, wherein the spatial optical differentiator is a Distributed Bragg Reflector (DBR) comprising alternating layers having high refractive index and low refractive index, wherein the DBR comprises 2 or more pairs of alternating layers, and wherein the high refractive index exceeds the low refractive index by about 0.2 or more.
